(19) United States
(12) Patent Application Publication
(10) Pub. No.: US 2026/0353606 A1
(43) Pub. Date: Nov. 5, 2026

(54) DYNAMIC COOLING SYSTEM FOR FLUID-COOLED ELECTRONIC CONTROL UNIT

(71) Applicant: Mobileye Vision Technologies Ltd., Jerusalem (IL)

(72) Inventor: Asaf DANILOV, Ramat Gan (IL)

(73) Assignee: Mobileye Vision Technologies Ltd., Jerusalem (IL)

(21) Appl. No.: 19/557,265

(22) Filed: Mar. 5, 2026

Related U.S. Application Data
(60) Provisional application No. 63/767,945, filed on Mar. 6, 2025.

(51) Int. Cl. H05K 7/20

(52) U.S. Cl. CPC H05K 7/20281; H05K 7/20245; H05K 7/20272; H05K 7/20872

(57) ABSTRACT

A dynamic cooling system for an electronic control unit (ECU) includes a pump, a cold plate configured to cool components in the ECU, and a control valve to control a flow rate of coolant fluid flowing through the cold plate. The system also includes a memory storing data and instructions, and a processor that executes the instructions to: receive signals from temperature sensors associated with respective components; receive target temperatures for the respective components; determine temperature differences between the temperatures of the components and their respective target temperatures; determine a target flow rate of the coolant fluid based on the temperature differences; and adjust at least one of the pump and the control valve to deliver the target flow rate of the coolant fluid to flow through the cold plate.

### CROSS-REFERENCE TO RELATED APPLICATION

This application claims the benefit of priority to U.S. Provisional Patent Application No. 63/767,945 filed on Mar. 6, 2025, the entire contents of which are incorporated by reference in this application.

### TECHNICAL FIELD

The present disclosure relates generally to technology for cooling an electronic control unit (ECU) using a cold plate and, for example, to systems and methods for dynamically adjusting a flow rate of coolant fluid flowing through the cold plate.

### BACKGROUND

An autonomous or semi-autonomous vehicle uses an ECU capable of receiving information from a variety of sensors, processing the received information, and issuing appropriate commands to various vehicle components for control and operation of the autonomous vehicle. The ECU typically includes a plethora of components including one or more processors, memories, printed circuit boards, and/or other electronic devices, some or all of which generate heat during operation of the ECU. The generated heat must be removed to prevent the temperature of the ECU and its components from exceeding safe limits for operation of the components in the ECU.

Although cooling systems for cooling ECU components exist, there is a need to significantly improve cooling efficiency. Improvements in electronics and control systems have resulted in significant increases in processing speeds of the processors in the ECU while the physical sizes of the components have decreased. Furthermore, the processors in the ECU may receive and process ever increasing amounts of information. The increased processing speed and/or increased amount of information to process results in ever increasing amounts of heat generation in the ECU. Furthermore, reductions in component sizes leads to higher heat generated per unit area (or heat flux) that may manifest as hot spots on one or more components of the ECU. Improvements in cooling efficiency are therefore desirable to provide cooling solutions to dissipate the ever increasing amount of heat generation and to provide adequate cooling for the hot spots in the ECU.

Some ECUs are cooled using a specialized cold-plate that comes into contact with one or more ECU components. Heat from the ECU components travels through the walls of the cold plate and is removed by the coolant fluid flowing through the cold plate. For example, the cold plate includes passageways allowing cold coolant fluid to enter the cold plate. As the coolant fluid flows through the cold plate, it absorbs heat from the walls of the cold plate and relatively warm or hot coolant fluid flows out of the cold plate. Thus, the coolant fluid flowing through the cold plate absorbs the heat flowing from the one or more ECU components through the walls of the cold plate, thereby cooling the ECU components.

In such conventional systems, the flow of coolant fluid through the cold plate is relatively constant. Thus, when the vehicle and/or ECU are operational, a predetermined amount of coolant fluid continues to flow through the cold plate. When the vehicle and/or ECU are turned off, coolant fluid flow through the cold plate may also be turned off. Such conventional ECU systems have numerous drawbacks. For example, because the flow rate of coolant fluid through the cold plate is relatively constant, the cooling system cannot adapt to varying thermal loads. Constant operation at a fixed flow rate of the coolant fluid leads to excessive power consumption and wear on cooling system components.

For example, when the ECU components are generating very little heat, a selected flow rate of the coolant fluid flowing through the cold plate may be excessive and may not be required to cool the ECU components to their target temperatures. In such conditions, excessive energy may be wasted in pumping the selected flow rate of the coolant fluid through the cold plate. In an electric vehicle (EV), every additional watt of energy used for cooling is a watt not available for propulsion, which in turn directly impacts the vehicle's range. Conversely, when the ECU components are generating a significant amount of heat, the selected flow rate of coolant fluid may not be sufficient to cool the ECU components to their desired target temperatures. When the ECU components operate at temperatures greater than their target temperatures, the ECU operation may be sub-optimal. Improvements in fluid-cooled ECU systems are therefore desirable to provide cooling solutions that optimize the use of the available energy while providing sufficient cooling to maintain the ECU components at their desired target temperatures.

### SUMMARY

In an embodiment, a dynamic cooling system for an electronic control unit (ECU) is disclosed. The system may include a pump configured to deliver a flow of coolant fluid to a cold plate configured to cool a plurality of components in the ECU. The system may also include at least one control valve configured to control a flow rate of the coolant fluid. Further, the system may include at least one memory configured to store data and instructions, and at least one processor configured to execute the instructions. The processor may be configured to receive, from a plurality of temperature sensors associated with the plurality of components, signals that are indicative of temperatures of the plurality of components. The processor may be configured to determine a plurality of target temperatures associated with respective ones of the plurality of components. The processor may be configured to determine a plurality of temperature differences associated with the plurality of components based on differences between the temperatures of the plurality of components and respective target temperatures associated with the plurality of components. The processor may be configured to determine a target flow rate of the coolant fluid based on the plurality of temperature differences. The processor may also be configured to adjust at least one of the pump and the at least one control valve to deliver the target flow rate of the coolant fluid to flow through the cold plate.

In an embodiment, a dynamic cooling system for an electronic control unit (ECU) is disclosed. The system may include a pump configured to deliver a flow of coolant fluid to a cold plate configured to cool a first component and a second component in the ECU. The system may also include at least one control valve configured to control a flow rate of the coolant fluid. Further, the system may include a first temperature sensor configured to determine a first temperature of the first component. The system may include a second temperature sensor configured to determine a second temperature of the second component. The system may also include at least one memory configured to store data and instructions, and at least one processor configured to execute the instructions. The processor may be configured to receive signals from the first temperature sensor and the second temperature sensor. The signals may be indicative of the first temperature and the second temperature, respectively. The processor may be configured to receive, from the memory, a first target temperature associated with the first component and a second target temperature associated with the second component. The processor may be configured to determine a first temperature difference associated with the first component based on the first temperature and the first target temperature. The processor may be configured to determine a second temperature difference associated with the second component based on the second temperature and the second target temperature. Further, the processor may be configured to determine a representative temperature difference based on the first temperature difference and the second temperature difference. The processor may also be configured to determine a target flow rate of the coolant fluid based on the representative temperature difference. The processor may be configured to adjust at least one of the pump and the at least one control valve to deliver the target flow rate of the coolant fluid to flow through the cold plate.

In an embodiment, a method for cooling components in an electronic control unit (ECU) is disclosed. The method may include receiving, from a first temperature sensor, a first temperature of a first component of the components in the ECU. The method may also include receiving, from a second temperature sensor, a second temperature of a second component of the components in the ECU. Further, the method may include determining a first temperature difference based on the first temperature and a first target temperature associated with the first component. The method may include determine a second temperature difference based on the second temperature and a second target temperature associated with the second component. The method may further include determining a representative temperature difference based on the first temperature difference and the second temperature difference. The method may include determining a target flow rate of a coolant fluid based on the representative temperature difference. The method may also include directing the target flow rate of the coolant fluid to flow through a cold plate configured to cool the components in the ECU.

In an embodiment, a dynamic cooling system for an electronic control unit (ECU) is disclosed. The system may include a pump configured to deliver a flow of coolant fluid to a cold plate configured to cool a plurality of components in the ECU. The system may also include at least one control valve configured to control a flow rate of the coolant fluid. Further, the system may include at least one processor comprising circuitry and a memory. The memory may include instructions that may be executed by the circuitry to cause the processor to perform the following operations. The processor may be configured to receive signals that are indicative of sensed temperatures of the plurality of components, the signals being based on detection signals of a plurality of temperature sensors associated with the plurality of components. The processor may be configured to receive a plurality of target temperature regimes associated with respective ones of the plurality of components. The processor may be configured to determine at least one flow rate parameter of the coolant fluid based on the sensed temperatures of the plurality of components and the plurality of target temperature regimes. The processor may also be configured to adjust at least one of the pump and the at least one control valve to modify a flow rate of the coolant fluid flowing through the cold plate, in response to the at least one flow rate parameter.

### BRIEF DESCRIPTION OF DRAWINGS

FIG. 1 illustrates an exemplary embodiment of an ECU for an autonomous vehicle, consistent with some embodiments of the present disclosure.

FIG. 2 illustrates a schematic of an exemplary cooling system for cooling the ECU of FIG. 1, consistent with some embodiments of the present disclosure.

FIG. 3 illustrates an exemplary method of cooling the ECU of FIG. 1, consistent with some embodiments of the present disclosure.

### DETAILED DESCRIPTION

The following detailed description refers to the accompanying drawings. Wherever possible, the same reference numbers are used in the drawings and the following description to refer to the same or similar parts. While several illustrative embodiments are described herein, modifications, adaptations and other implementations are possible. For example, substitutions, additions, or modifications may be made to the components illustrated in the drawings. Accordingly, the following detailed description is not limited to the disclosed embodiments and examples. Instead, the proper scope is defined by the appended claims.

Moreover, various terms used in the specification and claims may be defined or summarized differently when discussed in connection with differing disclosed embodiments. It is to be understood that the definitions, summaries, and explanations of terminology in each instance apply to all instances, even when not repeated, unless the transitive definition, explanation or summary would result in inoperability of an embodiment.

Throughout, this disclosure mentions “disclosed embodiments,” which refer to examples of inventive ideas, concepts, and/or manifestations described herein. Many related and unrelated embodiments are described throughout this disclosure. The fact that some “disclosed embodiments” are described as exhibiting a feature or characteristic does not mean that other disclosed embodiments necessarily share that feature or characteristic.

This disclosure employs open-ended permissive language, indicating for example, that some embodiments “may” employ, involve, or include specific features. The use of the term “may” and other open-ended terminology is intended to indicate that although not every embodiment may employ the specific disclosed feature, at least one embodiment employs the specific disclosed feature.

Some embodiments involve a dynamic cooling system for an electronic control unit (ECU). An ECU, also known as an electronic control module (ECM), may include one or more electronic devices and circuitry that may be configured to control one or more electrical systems or subsystems. In some embodiments, the one or more electrical systems or subsystems may be embodied in an automotive vehicle (e.g., an autonomous vehicle or a semi-autonomous vehicle). The ECU may be configured to receive one or more signals from one or more sensors and/or input devices of the automotive vehicle and may be configured to issue one or more commands to control one or more components and or actuators of the automotive vehicle for one or more operations associated with the automotive vehicle. Although the ECU is described above in the context of an automotive vehicle, the ECU may additionally or alternatively be configured to control operations of a marine vehicle, an airborne vehicle, or a stationary or mobile electrical device or system. The ECU may include components such as one or more processors, memory devices, and/or other electronic devices including but not limited to graphics chips, communication devices, input/output controllers, resistors, capacitors, inductors, relays, switches, buses, and/or any other type of electronic device required for controlling an operation of the autonomous or semi-autonomous vehicle.

A cooling system may refer to an arrangement of hardware and/or software components configured to direct the flow of a coolant fluid (e.g., liquid or gaseous coolant) to remove heat from the one or more components. For example, an exemplary cooling system may include an arrangement of hardware and software components configured to direct the flow of a coolant fluid (e.g., liquid or gaseous coolant) to remove heat from the one or more components of the ECU, and thereby cool the ECU. A dynamic cooling system may refer to a cooling system in which one or more characteristics of the cooling system may be adjustable. For example, in a dynamic cooling system, the flow rate (e.g., volume flow rate or mass flow rate) of the coolant fluid, direction of the coolant fluid, temperature of the coolant fluid, speed of a motor or pump associated with the cooling system, movable element of a valve, or other system parameters may be adjustable periodically or continuously.

In some embodiments, the ECU includes a first printed circuit board comprising a plurality of first components and a second printed circuit board comprising a plurality of second components, the first components and the second components being included in the plurality of components. A printed circuit board may refer to a laminated sandwich planar structure of conductive and insulating layers, where each of the conductive layers may be shaped or patterned to help connect different portions of the printed circuit board. A printed circuit board may also include one or more components mounted on either surface of the planar structure of the printed circuit board. The conductive layers in the printed circuit board may be configured to electrically connect one or more of the components attached to the printed circuit board to each other. In some embodiments, the ECU may include one or more printed circuit boards and some or all of the plurality of components of the ECU may be mounted to the planar surfaces of the one or more printed circuit boards.

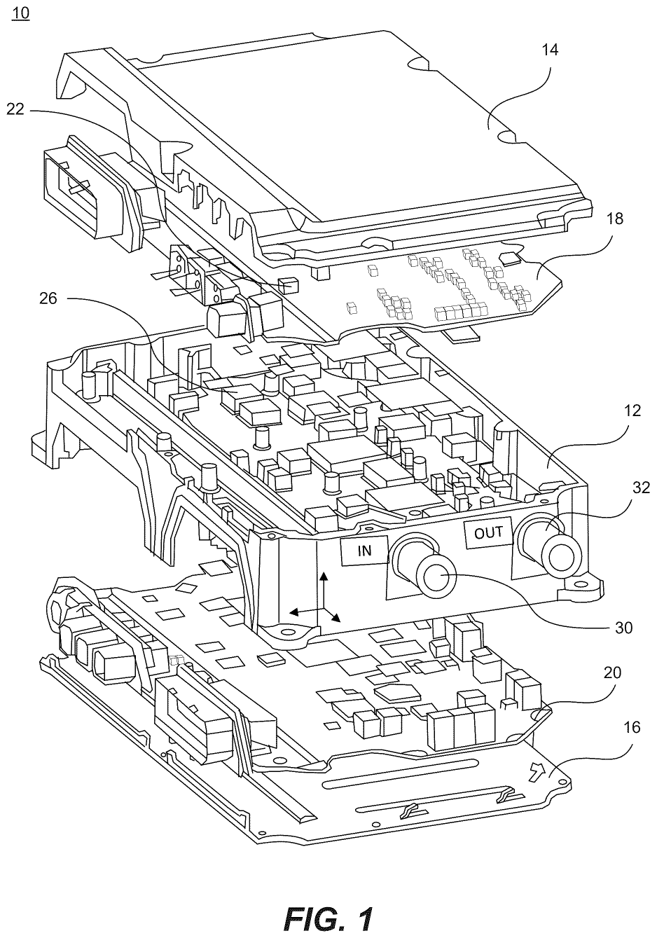

By way of example, FIG. 1 illustrates an exemplary embodiment of an electronic control unit (ECU) 10 for a vehicle. ECU 10 may include cold plate 12, first cover 14 (e.g., upper cover), second cover 16 (e.g., lower cover), component assembly 18, and component assembly 20. First cover 14 and second cover 16 may form an enclosure when mated with each other. Cold plate 12 and component assemblies 18 and 20 may be disposed within the enclosure formed by first and second covers 14 and 16. Component assembly 18 may include one or more components 22 (e.g., electronic devices) and similarly component assembly 20 may include one or more components 22. The one or more components 22 may include one or more processors, memory devices, and/or other electronic devices including but not limited to graphics chips, communication devices, input/output controllers, resistors, capacitors, inductors, and/or any other type of electronic device required for controlling an operation of the vehicle. In some exemplary embodiments, one or both of component assemblies 18 and 20 may include one or more printed circuit boards or substrates and the one or more components 22 may be attached to or mounted to the one or both sides of the one or more printed circuit boards.

In one exemplary embodiment as illustrated in FIG. 1, component assemblies 18 and 20 may be positioned on either side of cold plate 12. It should be understood, however, that one or both component assemblies 18 and 20 may be located on one side of or both sides of cold plate 12. That is, in some exemplary embodiments, one or both component assemblies 18 and 20 may be located between first cover 14 and cold plate 12 or between second cover 16 and cold plate 12. It is also contemplated that some exemplary embodiments may include only one of component assemblies 18 and 20 but not both.

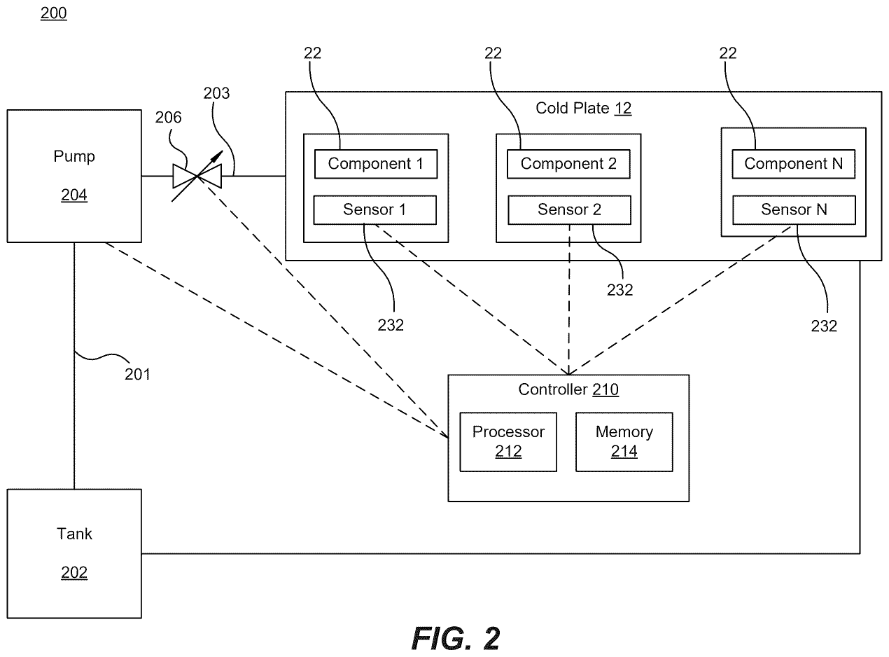

Cold plate 12 may include one or more protrusions 26 that may be configured to come into contact with one or more components 22. Protrusions 26 may help to conduct heat generated by the one or more components 22 to cold plate 12. As also illustrated in FIG. 1, cold plate 12 may include inlet 30 and outlet 32. Inlet 30 may be configured to allow coolant fluid to enter cold plate 12. The coolant fluid may be configured to absorb heat from the inner walls of the cold plate. The coolant fluid may be discharged from cold plate 12 via outlet 32. In some exemplary embodiments, pump 204 (see FIG. 2) may be configured to cause the coolant fluid to flow into cold plate 12 via inlet 30 and flow out of cold plate 12 via outlet 32. The coolant fluid may include water, mixture of water and ethylene glycol or alcohol, or any other coolant fluid that can be used to absorb heat from the surfaces of cold plate 12. The configuration of ECU 10 and cold plate 12 illustrated in FIG. 1 and described above are exemplary and nonlimiting. Components 22 may be arranged in and may come into contact with cold plate 12 in other ways to allow heat from components 22 to be conveyed to the coolant fluid flowing within cold plate 12.

In some embodiments, the system includes a pump configured to deliver a flow of coolant fluid to a cold plate configured to cool a plurality of components in the ECU. In some embodiments, the system includes a pump configured to deliver a flow of coolant fluid to a cold plate configured to cool a first component and a second component in the ECU. As used herein, the term “cold plate” broadly includes any system or device for removing heat by a coolant fluid flowing through the device. The cold plate may be directly or indirectly attached to one or more electronic devices, components, or systems that may generate heat. The generated heat may enter the cold plate. A coolant fluid flowing through the cold plate may absorb the heat, which may be removed by warm coolant fluid flowing out of the cold plate. For example, relatively cold coolant fluid may enter the cold plate, absorb the heat generated by the one or more electronic devices, components, or systems, and relatively warm coolant fluid may exit the cold plate. Thus, the relatively warm coolant fluid exiting the cold plate may remove heat generated by the one or more components.

A pump may refer to a device configured to receive coolant fluid from a sump, tank, or other storage of coolant fluid, pressurize the coolant fluid, and direct the pressurized coolant fluid to flow, for example, through a cold plate of the cooling system. The pump may be configured to establish a pressure differential between an inlet and an outlet of the pump that may cause the coolant fluid to flow through the pump and through the cooling system. For example, in some embodiments, the pump may be configured to receive coolant fluid (e.g., liquid or gaseous coolant) from a sump, and cause the coolant fluid to flow through a cold plate configured to cool the components of the ECU. The pump may include, for example, centrifugal pump, a positive displacement pump, a vane pump, a fixed capacity, variable displacement pump, or any type of mechanism configured to move the coolant fluid through the cooling system. In some embodiments, a speed of the pump or a motor associated with the pump may be adjustable and may allow for adjustment of the flow rate of the coolant fluid through the cooling system. For example, increasing a speed of the pump may cause a higher flow rate of the coolant fluid to flow through the cooling system, while decreasing the speed may cause a lower flow rate of the coolant fluid to flow through the cooling system.

In some embodiments, the pump is configured to deliver a predetermined flow rate of the coolant fluid. A pump associated with the cooling system may have a maximum or design flow rate of coolant fluid that the pump is capable of delivering. For example, the maximum rotational speed at which a pump can be operated may be determined based on the capacity of a prime mover (e.g., engine or motor) driving the pump, or by a maximum speed rating of a bearing or other components associated with the pump. The size and design of the pump may allow the pump to deliver the maximum or design flow rate of the coolant fluid when, for example, the pump is operated at its maximum speed. As used in this disclosure, the predetermined flow rate of the pump refers to the maximum or design flow rate of the coolant fluid capable of being delivered by the pump. It should be understood that different pumps and different cooling system designs may allow for different maximum or design flow rates (i.e., different predetermined flow rates) of the coolant fluid.

In some embodiments, the system includes at least one control valve configured to control a flow rate of the coolant fluid. A valve may refer to a device configured to regulate, or control the flow of a fluid (e.g., coolant fluid) by opening, closing, or partially obstructing one or more passageways. A control valve may refer to a valve used to control fluid flow by varying the size of an opening in a passageway based on a signal from a controller. For example, the control valve may include a movable element that may have a fully open position in which an entire cross-sectional areas of the passageway may be available for the flow of the coolant fluid, allowing coolant fluid to flow in the passageway unobstructed. The movable element of may be movable from its fully open position to its fully closed position in which flow of coolant fluid in the passageway may be completely blocked. At intermediate positions between the fully open and fully closed positions, the control valve may allow some amount or flow rate of coolant fluid that may be a fraction of the amount that can flow when the movable element is in its open position (e.g., fully open). In some embodiments, one or both of the pump and/or the control valve may be adjusted to control the flow rate of the coolant fluid through the cold plate.

In some embodiments, the system includes a plurality of temperature sensors associated with respective ones of the components. In some embodiments, the system includes a first temperature sensor configured to determine a first temperature of the first component. In some embodiments, the system includes a second temperature sensor configured to determine a second temperature of the second component. A temperature sensor may refer to a device capable of generating a signal representative of a temperature of an object associated with the temperature sensor. In some embodiments, the temperature sensor may be in contact with the object, whereas in other embodiments, the temperature sensor may be spaced apart from the object by a gap. In some embodiments, the temperature signal may directly indicate the temperature, whereas in other embodiments, a controller or processor may convert the signal into a temperature value. A temperature sensor may include, for example, a thermocouple, a thermistor, a thermopile, a resistance thermometer, a silicon bandgap thermometer, an infrared thermometer, or any other device capable of determining a temperature of an associated object. In some embodiments, different components of the ECU may have different temperature sensors associated with them. For example, a first component of the ECU may have an associated first temperature sensor configured to provide a first temperature of the first component. Similarly, a second component of the ECU may have an associated second temperature sensor configured to provide a second temperature of the first component. A third component of the ECU may have an associated third temperature sensor configured to provide a third temperature of the first component, and so on. In some embodiments, more than one temperature sensor may be associated with a component.

In some embodiments, the system includes at least one processor configured to execute the instructions. A processor may refer to any physical device or group of devices having electric circuitry that performs a logic operation on an input or on inputs. For example, the at least one processor may include one or more integrated circuits (IC), including application-specific integrated circuit (ASIC), microchips, microcontrollers, microprocessors, all or part of a central processing unit (CPU), graphics processing unit (GPU), digital signal processor (DSP), field-programmable gate array (FPGA), server, virtual server, or other circuits suitable for executing instructions or performing logic operations. The instructions executed by at least one processor may, for example, be pre-loaded into a memory integrated with or embedded into the controller or may be stored in a separate memory.

In some embodiments, the at least one processor may include more than one processor. Each processor may have a similar construction, or the processors may be of differing constructions that are electrically connected or disconnected from each other. For example, the processors may be separate circuits or integrated in a single circuit. When more than one processor is used, the processors may be configured to operate independently or collaboratively and may be co-located or located remotely from each other. The processors may be coupled electrically, magnetically, optically, acoustically, mechanically or by other means that permits them to interact.

In some embodiments, the system includes at least one memory configured to store data and instructions. A memory may refer to any non-transitory medium capable of storing data that may be read by any computing device with a processor to carry out methods or any other instructions stored in the memory. For example, the term memory may include a Random Access Memory (RAM), a Read-Only Memory (ROM), a hard disk, an optical disk, a magnetic medium, a flash memory, other permanent, fixed, or volatile memory, or any other mechanism capable of storing instructions. Memory may include one or more separate storage devices collocated or disbursed, capable of storing data structures, instructions, or any other data. Memory may further include a memory portion containing instructions for the processor to execute. The memory may also be used as a working scratch pad for a processor or as a temporary storage.

By way of example, FIG. 2 shows a schematic view of an exemplary dynamic cooling system 200. Dynamic cooling system 200 may include cold plate 12, tank 202, pump 204, valve 206, one or more temperature sensors 232, and controller 210. Tank 202 may be configured to store coolant fluid. The coolant fluid may include water, mixture of water and ethylene glycol or alcohol, or any other coolant fluid that can be used to absorb heat from the surfaces of cold plate 12. Pump 204 may be configured to draw coolant fluid from tank 202 via fluid connection 201 and direct the coolant fluid to inlet 30 of cold plate 12 via fluid connection 203. Pump 204 may be driven by one or more motors (not shown). Although only one pump 204 is shown in FIG. 2, any number of pumps 204 may be included in dynamic cooling system 200. Coolant fluid may flow through cold plate 12 and may be returned to tank 202 via fluid connection 205. Because coolant fluid exiting cold plate 12 may be warm or hot, one or more heat exchangers may be disposed in fluid connection 205 to help reduce a temperature of the coolant fluid before the coolant fluid is returned to tank 202. Fluid connections 201, 203, and 205 may include one or more tubes or piping configured to allow a flow of the coolant fluid between the various components of cooling system 200.

Valve 206 may be disposed in fluid connection 203 between pump 204 and cold plate 12. Valve 206 may be configured to control an amount and/or flow rate of coolant fluid flowing into inlet 30 of cold plate 12. Valve 206 may include a movable element that may be movable from a fully open first position to a fully closed position. Valve 206 may be a control valve. As will be explained below, controller 210 may be configured to adjust the movable element of valve 206 between its fully open and fully closed positions to control the amount or flow rate of coolant fluid flowing into inlet 30 of cold plate 12. Although only one valve 206 is shown in FIG. 2, any number of valves 206 may be included in dynamic cooling system 200. Further, one or more valves 206 may additionally or alternatively be included in fluid connections 201 and/or 205 and each of the valves 206 may be controllable via controller 210.

As illustrated in FIG. 2, cold plate 12 may be configured to cool one or more components (e.g., component 1, component 2, . . . component N) of ECU 10. For example, as illustrated, cold plate 12 may be configured cool components 22. Although three components 22 have been illustrated in FIG. 2, cold plate 12 may be configured to cool any number N of components 22. Each of components 22 (e.g., component 1, component 2, . . . component N) may be equipped with a temperature sensor (e.g., sensor 1, sensor 2, . . . sensor N). For example, as illustrated in FIG. 2, each component 22 may have an associated temperature sensor 232. Although each component 22 has been illustrated as having one temperature sensor 232, each component 22 may include any number of temperature sensors 232. Further, although not illustrated in FIG. 2, dynamic cooling system 200 may include one or more additional sensors, for example, pressure sensors or flow sensors disposed in one or more of fluid connections 201, 203, 205. The one or more flow sensors may be configured to measure a flow rate of coolant fluid flowing through fluid connections 201, 203, 205 and/or cold plate 12.

As illustrated in FIG. 2, controller 210 may include processor 212 and memory 214. Controller 210 may embody a single microprocessor (e.g., processor 212) or multiple microprocessors, digital signal processors (DSPs), or electronic circuitry that include means for controlling an operation of pump 204 and/or valve 206. Numerous commercially available microprocessors can be configured to perform the functions of controller 210. Memory 214 may embody non-transitory computer-readable media, for example, Random Access Memory (RAM) devices, NOR or NAND flash memory devices, and Read Only Memory (ROM) devices, CD-ROMs, hard disks, floppy drives, optical media, solid state storage media, or other types of electronic data and instruction storage devices. Processor 212 of controller 210 may be configured to execute instructions stored in memory 214.

In some embodiments, the cooling control logic is based on temperature deviation relative to component-specific thermal targets rather than on absolute temperature measurements alone. For each monitored component, the processor may determine a thermal deviation value representing the difference between the measured temperature and the respective target temperature. The cooling demand of the system may be expressed as a function of the available thermal margin for each component. By basing the cooling request on deviation from target operating conditions, the system may be capable of dynamically adjusting coolant flow in a manner that directly reflects the real thermal state of the ECU rather than relying on a fixed or single-sensor temperature threshold.

In contrast to conventional cooling strategies that rely on a single hotspot sensor or global temperature limit, the disclosed system may evaluate thermal conditions of a plurality of components concurrently. Each component may contribute to the determination of the cooling request through its respective temperature deviation relative to its target operating temperature. The cooling control algorithm therefore may perform a system-level optimization in which the thermal requirements of multiple components are evaluated simultaneously to determine an appropriate coolant flow rate. This may enable the cooling system to maintain safe operating conditions across multiple heat sources within the ECU while avoiding excessive cooling that would otherwise result from relying on a single measurement point.

The processor may determine a representative thermal deviation from a plurality of component-specific temperature deviations. The representative deviation may be derived using one or more aggregation methods including selecting a maximum deviation, calculating an average deviation, or applying a weighted or statistical combination of deviations associated with different components. The representative deviation may then be used as a control parameter for determining the coolant flow rate. By converting multiple thermal measurements into a single representative control parameter, the system may simplify cooling control while still reflecting the thermal state of multiple components.

As discussed above, the ECU may include multiple printed circuit boards each containing independent heat-generating components. The cooling system may evaluate thermal deviations separately for each circuit board and determine an intermediate cooling demand associated with each board. A final coolant flow request may then be determined based on a combination of the board-level cooling demands, such as selecting the maximum or another aggregated value. This approach may enable coordinated cooling across multiple electronic assemblies while ensuring that the cooling system satisfies the thermal requirements of the most thermally demanding board.

In some embodiments, the at least one processor is configured to receive signals from the plurality of temperature sensors, the signals being indicative of temperatures of the plurality of components. In some embodiments, the at least one processor is configured to receive signals from the first temperature sensor and the second temperature sensor, the signals being indicative of the first temperature and the second temperature, respectively. In some embodiments, the at least one processor is configured to receive signals that are indicative of sensed temperatures of the plurality of components, the signals being based on detection signals of a plurality of temperature sensors associated with the plurality of components. Receiving signals may refer to acquiring, obtaining, retrieving, or otherwise gaining access to one or more signals from one or more temperature sensors, pressure sensors, flow sensors, or any other type of sensors associated with the cooling system. As discussed above, in some embodiments, the ECU may include one or more components and one or more temperature sensors may be configured to measure the temperature of an associated component. Each temperature sensor may generate one or more signals representative of the temperature of an associated component. In some embodiments, the signal generated by the temperature sensor may be conditioned by, for example, filtering, smoothing, transforming, or performing various other mathematical or signal processing operations. One or more processors of the ECU and/or the dynamic cooling system may receive the signals generated by the one or more temperature sensors or the conditioned signals that may be indicative of the sensed temperatures of the plurality of components associated with the plurality of temperature sensors. In some embodiments, a signal received from a temperature sensor may be representative of a temperature of an associated component. For example, the signal may be in the form of a voltage and the processor may be configured to convert the voltage into a temperature value. Thus, the one or more processors of the ECU and/or the dynamic cooling system may be configured to receive one or more signals from the one or more temperature sensors and determine a temperature of a component associated with a respective temperature sensor.

By way of example referring to FIG. 2, processor 212 of controller 210 may receive signals from the one or more temperature sensors 232 indicative of temperature of the one or more components 22 (e.g., component 1 through component N). For example, temperature sensors 232 associated with components 22 may measure temperatures T₁, T₂, . . . T_{N} corresponding to component 1, component 2, . . . component N, respectively. In some embodiments, temperatures T₁, T₂, . . . T_{N} may correspond to junction temperatures of one or more components 22 (e.g., component 1 through component N). As another example, processor 212 may receive a first signal from a first temperature sensor and may convert that signal to a temperature T₁ associated with a first component, namely component 1. Similarly, for example, processor 212 may receive a second signal from a second temperature sensor and may convert that signal to a temperature T₂ associated with a second component, namely component 2.

In some embodiments, the at least one processor is configured to determine a plurality of target temperatures associated with respective ones of the plurality of components. In some embodiments, the at least one processor is configured to determine the target temperatures by receiving, from the memory, the plurality of target temperatures associated with respective ones of the plurality of components. In some embodiments, the at least one processor is configured to receive, from the memory, a first target temperature associated with the first component and a second target temperature associated with the second component. Each of the one or more components may have an associated target temperature. The target temperature may represent a temperature above which the component cannot operate safely or cannot operate as desired. In some embodiments, more than one component may have the same target temperature. In other embodiments, different components may have different target temperatures. The target temperatures associated with the one or more components may be stored in a memory associated with the cooling system. For example, the target temperatures may be stored in a database, a look-up table, a data structure, or using any other method of associating a target temperature with a corresponding component. In some embodiments, a target temperature for a component may be stored in association with an identifier of the component in a database, look-up table, or data structure.

Receiving from memory may refer to reading, retrieving, acquiring, obtaining, or otherwise gaining access to data or instructions stored in the memory. In some embodiments, one or more processors of the ECU and/or the dynamic cooling system may be configured to receive the target temperatures stored in association with corresponding components from the memory. By way of example referring to FIG. 2, each of components 22 (e.g., component 1 through component N) may have an associated target temperature. For example, component 1 may have a target temperature T_{TARGET-1}, component 2 may have a target temperature T_{TARGET-2}, component N may have a target temperature T_{TARGET-N}, and so on. In some embodiments, the first target temperature is different from the second target temperature. Target temperatures T_{TARGET-1}, T_{TARGET-2}, . . . T_{TARGET-N} may be equal or unequal. For example, the first target temperature, T_{TARGET-1}, may be higher than or lower than the second target temperature, T_{TARGET-2}, or vice-versa. In some embodiments, one or more target temperatures may be equal. Target temperatures T_{TARGET-1}, T_{TARGET-2}, . . . T_{TARGET-N} may be predetermined and stored in, for example, memory 214. In some exemplary embodiments, target temperatures T_{TARGET-1}, T_{TARGET-2}, . . . T_{TARGET-N} may be a function of one or more vehicle operational parameters, and/or ambient conditions (e.g., temperature, pressure, humidity, altitude) and may be determined by processor 212 using a mathematical expression, an algorithm, or a look-up table.

In some embodiments, the at least one processor may be configured to determine the target temperatures by, for example, employing a look up table, one or more correlations, equations, mathematical or physical models, and/or algorithms to determine the target temperatures. In some exemplary embodiments, one or more processors of the ECU and/or the dynamic cooling system (e.g., processor 212) may employ one or more trained systems or trained machine learning models to determine the target temperatures for one or more of the plurality of components based on parameters such as vehicle speed, vehicle weight, ambient temperature, ambient pressure, ambient humidity, and/or any other parameter that may have an impact on the temperature of the one or more components. The one or more trained systems or trained machine learning models may employ learning algorithms, for example, classification algorithms, data regressions algorithms, mathematical embedding algorithms, Natural language processing algorithms, support vector machines, random forests, Nearest Neighbors algorithms, deep learning algorithms, artificial Neural Network algorithms, convolutional Neural Network algorithms, recursive Neural Network algorithms, linear machine learning models, Non-linear machine learning models, ensemble algorithms, and so forth. The one or more trained systems or trained machine learning models may be trained using a training data set that may relate parameters such as vehicle speed, vehicle weight, ambient temperature, ambient pressure, ambient humidity, and/or any other parameter with associated target temperatures.

In some embodiments, the at least one processor may be configured to determine target temperature regimes instead of or in addition to target temperatures. A target temperature regime may include a range of target temperatures, a function that relates the target temperature to one or more parameters discussed above, and/or a model or algorithm for determining the target temperature. For example, each component may have an associated target temperature regime.

In some embodiments, the at least one processor is configured to determine a plurality of temperature differences associated with the plurality of components based on differences between the temperatures of the plurality of components and respective target temperatures associated with the plurality of components. In some embodiments, the at least one processor is configured to determine a first temperature difference associated with the first component based on the first temperature and the first target temperature. In some embodiments, the at least one processor is configured to determine a second temperature difference associated with the second component based on the second temperature and the second target temperature. For example, the one or more processors of the ECU and/or the dynamic cooling system may subtract the temperature of a component (e.g., obtained from a temperature sensor associated with that component) from the target temperature for that component (e.g., obtained from the memory). In some embodiments, the one or more processors of the ECU and/or the dynamic cooling system may be configured to perform this operation for all components of the ECU that have an associated temperature sensor. This may result in generation of a plurality of temperature differences associated with a plurality of components of the ECU. In some embodiments, the one or more processors of the ECU and/or the dynamic cooling system may be configured to perform this operation for only some of the components of the ECU that have an associated temperature sensor. For example, the processor may be configured to determine temperature differences only for some critical components, the failure of which may prevent safe and effective operation of the vehicle or the cooling system.

By way of example, referring to FIG. 2, processor 212 may determine a first temperature difference ΔT₁ for component 1 as the difference T₁−T_{TARGET-1}. Similarly, processor 212 may determine a second temperature difference ΔT₂ for component 2 as the difference T₂−T_{TARGET-2}, an Nth temperature difference ΔT_{N} for component N as the difference T_{N}−T_{TARGET-N}, and so on. Although a difference in temperatures has been discussed above, in some exemplary embodiments, processor 212 may determine a ratio of the measured and target temperatures for each component or may use any other type of statistical calculation or algorithm to determine a resultant value based on the measured and target temperatures for each component 22. It should be understood that all the operations described in the remainder of this disclosure with respect to temperature differences may be similarly performed using the resultant values.

In some embodiments, the at least one processor is configured to determine a representative temperature difference based on the plurality of temperature differences. In some embodiments, the at least one processor is configured to determine a representative temperature difference based on the first temperature difference and the second temperature difference. In some embodiments, the representative temperature difference is a maximum value of the plurality of temperature differences. In some embodiments, the representative temperature difference is a maximum value of the first temperature difference and the second temperature difference. In some embodiments, the representative temperature difference is an average value of the plurality of temperature differences. In some embodiments, the representative temperature difference is an average value of the first temperature difference and the second temperature difference. The one or more processors of the ECU and/or the dynamic cooling system may determine a single temperature difference value or a single resultant value based on the plurality of temperature difference values or resultant values, respectively, determined for the plurality of components of the ECU. The single temperature difference value (or representative temperature difference) or single resultant value may be determined based on performing one or more mathematical operations on the plurality of temperature difference values or resultant values, respectively, determined for the plurality of components of the ECU. In one embodiment, the processor may determine a maximum temperature difference from the plurality of temperature difference values determined for the plurality of components of the ECU, and select that maximum temperature difference value as the representative temperature difference. In another embodiment, the processor may determine an average of the plurality of temperature difference values determined for the plurality of components of the ECU, and select that average temperature difference value as the representative temperature difference. It should be understood that the processor may perform other statistical calculations, and/or apply one or more mathematical expressions and/or algorithms to the plurality of temperature difference values to derive the representative temperature difference.

By way of example, referring to FIG. 2, processor 212 may determine the representative temperature difference as a maximum value of the temperature differences. For example, the representative temperature difference may be a maximum value of ΔT₁, ΔT₂, . . . ΔT_{N}. In some exemplary embodiments, processor 212 may determine the representative temperature difference as an average, median, mode, or any other statistical quantity based on the temperature differences determined. As another example, when processor 212 determines the first temperature difference ΔT₁ for a first component and the second temperature difference ΔT₂ for the second component, processor 212 may determine the representative temperature difference as the greater of ΔT₁ and ΔT₂, or an average of ΔT₁ and ΔT₂. In some embodiments, processor 212 may determine the representative temperature difference based on any other mathematical combination of the temperature differences ΔT₁, ΔT₂, . . . ΔT_{N} or by performing operations on one or more the temperature differences ΔT₁, ΔT₂, . . . ΔT_{N}, using any correlations, equations, or algorithms. Processor 212 may determine a representative resultant value by performing one or more operations similar to those discussed above on the one or more resultant values.

In some embodiments, the at least one processor is configured to receive, from the memory, a plurality of threshold temperature difference ranges and a range flow rate associated with each of the plurality of threshold temperature difference ranges. In some embodiments, each threshold temperature difference range includes at least a lower threshold temperature difference and an upper threshold temperature difference. In some embodiments, each of the threshold temperature difference ranges is associated with a fraction of the predetermined flow rate. In some embodiments, a set of threshold temperature difference ranges may be stored in a memory associated with the cooling system. In some embodiments, the threshold temperature difference range may be defined by a lower threshold temperature difference (e.g., ΔT_{LOW}) and an upper threshold temperature difference (e.g., ΔT_{HIGH}). Thus, the threshold temperature difference range may include a temperature difference greater than the lower threshold temperature difference and smaller than or equal to the upper threshold temperature difference. For example, the threshold temperature difference range may be defined by the expression ΔT_{LOW}<ΔT≤ΔT_{HIGH}. Further, a range flow rate of the coolant fluid may be stored in association with each of the threshold temperature difference ranges in the memory. For example, a range flow rate F₁ may be associated with the threshold temperature difference range ΔT_{LOW}<ΔT≤ΔT_{HIGH}. Thus, the memory may store a plurality of threshold temperature difference ranges in association with corresponding range flow rates in a database, data structure, look-up table, or any other method of associating a threshold temperature difference range with a corresponding range flow rate.

By way of example, in some embodiments, the memory may include five threshold temperature difference ranges and associated range flow rates as follows:
Range 1: ΔT≤ΔT_{Limit-1} Flow Rate 1
Range 2: ΔT_{Limit-1}<ΔT≤ΔT_{Limit-2} Flow Rate 2
Range 3: ΔT_{Limit-2}<ΔT≤ΔT_{Limit-3} Flow Rate 3
Range 4: ΔT_{Limit-3}<ΔT≤ΔT_{Limit-4} Flow Rate 4
Range 5: ΔT>ΔT_{Limit-4} Flow Rate 5
   In one exemplary embodiment, Flow Rate 1, Flow Rate 2, Flow Rate 3, Flow Rate 4, and Flow Rate 5 may be 20%, 40%, 60%, 80%, and 100%, respectively, of a predetermined or maximum flow rate of the coolant fluid. In some embodiments, Flow Rate 2, Flow Rate 3, Flow Rate 4, and Flow Rate 5 may be 2× (i.e., 2 times), 3× (i.e., 3 times), 4× (i.e., 4 times), and 5× (i.e., 5 times) Flow Rate 1, respectively. Thus, for example, threshold temperature difference range, Range 3, may be defined by lower threshold temperature difference ΔT_{Limit-2} and upper threshold temperature difference ΔT_{Limit-3}, and may have an associated range flow rate, Flow Rate 3 (e.g., 60% of the maximum flow rate). The one or more processors of the ECU and/or the dynamic cooling system may be configured to receive the plurality of threshold temperature difference ranges and associated range flow rates from stored in a memory associated with the ECU or cooling system.

In some embodiments, the at least one processor is configured to compare the representative temperature difference with a plurality of threshold temperature difference ranges. In some embodiments, the at least one processor is configured to identify a threshold temperature difference range corresponding to the representative temperature difference, the identified threshold temperature difference range being one of the plurality of threshold temperature difference ranges. For example, the one or more processors of the ECU and/or the dynamic cooling system may compare the representative temperature difference with the lower and upper threshold temperature differences associated with each threshold temperature difference range. The processor may be configured to identify the threshold temperature difference range that encompasses the representative temperature difference. For example, returning to the example above, processor 212 may be configured to compare the representative temperature difference with the lower and upper threshold temperature differences of each of Range 1, Range 2, Range 3, Range 4, and Range 5. As an example, processor 212 may identify Range 2 as a threshold temperature difference range that corresponds to the representative temperature difference when the representative temperature difference is greater than ΔT_{Limit-1} and less than or equal to ΔT_{Limit-2}.

In some embodiments, the at least one processor may be configured to determine at least one flow rate parameter of the coolant fluid based on the sensed temperatures of the plurality of components and the plurality of target temperature regimes. In some embodiments, the flow rate parameter may be an indicator such as “higher flow rate needed” or “lower flow rate needed.” In some embodiments, the at least one processor may be configured to determine the required or target flow rate based on the indicator and, for example, one or more look up table, correlations, algorithms, models, of trained machine learning models similar to those discussed elsewhere in this disclosure. In some embodiments, the flow rate parameter may be a target flow rate.

In some embodiments, the at least one processor may be configured to determine the at least one flow rate parameter based on the sensed temperature of the plurality of components and the target temperature regimes associated with the components. For example, the at least one processor may use a model, algorithm, or a trained machine learning model to determine the at least one flow rate parameter using the sensed temperature of the plurality of components and the target temperature regimes associated with the components. For example, a target temperature regime may include a range of temperatures. The at least one processor may be configured to determine a target flow rate based on how close a component temperature lies to the lower and/or upper ends of the temperature range of the target temperature regime. As discussed, the at least one processor may determine the target flow rate using look up tables, correlations, models, algorithms, or trained machine learning models, similar to those discussed elsewhere in this disclosure.

In some embodiments, the at least one processor is configured to determine the target flow rate based on the representative temperature difference. In one exemplary embodiment, the one or more processors of the ECU and/or the dynamic cooling system (e.g., processor 212) may employ a look up table to determine the coolant fluid flow rate corresponding to the representative temperature difference or the representative resultant value. In one exemplary embodiment, one or more processors of the ECU and/or the dynamic cooling system (e.g., processor 212) may employ one or more correlations, equations, mathematical or physical models, or algorithms to determine the coolant fluid flow rate corresponding to the representative temperature difference or the representative resultant value.

In some exemplary embodiments, one or more processors of the ECU and/or the dynamic cooling system (e.g., processor 212) may employ one or more trained systems or trained machine learning models to determine the coolant fluid flow rate corresponding to the representative temperature difference or the representative resultant value, and/or based on the measured temperatures T₁, T₂, . . . T_{N}, the target temperatures T_{TARGET-1}, T_{TARGET-2}, . . . T_{TARGET-N}, and/or one or more other parameters such as vehicle speed, vehicle weight, ambient temperature, ambient pressure, ambient humidity, and/or any other parameter that may have an impact on the operation of the vehicle or the ECU. The one or more trained systems or trained machine learning models may employ learning algorithms, for example, classification algorithms, data regressions algorithms, mathematical embedding algorithms, Natural language processing algorithms, support vector machines, random forests, Nearest Neighbors algorithms, deep learning algorithms, artificial Neural Network algorithms, convolutional Neural Network algorithms, recursive Neural Network algorithms, linear machine learning models, Non-linear machine learning models, ensemble algorithms, and so forth.

The one or more trained systems or trained machine learning models may be trained using a training data set that may relate measured temperatures, for example, T₁, T₂, . . . T_{N}, the target temperatures, for example, T_{TARGET-1}, T_{TARGET-2}, . . . T_{TARGET-N}, and/or one or more other parameters such as vehicle speed, vehicle weight, ambient temperature, ambient pressure, ambient humidity, and/or any other parameter that may have an impact on the operation of the vehicle or the ECU to associated coolant fluid flow rates.

In some embodiments, the at least one processor is configured to determine a range flow rate associated with the identified threshold temperature difference range. In some embodiments, the at least one processor is configured to determine a range flow rate associated with the identified threshold temperature difference range. For example, one or more processors of the ECU and/or the dynamic cooling system (e.g., processor 212) may determine which of the ranges (e.g., Range 1, Range 2, Range 3, Range 4, Range 5) encompasses the representative temperature difference. When the representative temperature difference lies, for example, in Range 2 (e.g., the representative temperature difference is greater than ΔT_{Limit-1} and less than or equal to ΔT_{Limit-2}), one or more processors of the ECU and/or the dynamic cooling system (e.g., processor 212) may determine the coolant fluid flow rate as Flow Rate 2. Similarly, for example, when the representative temperature difference lies in Range 4, one or more processors of the ECU and/or the dynamic cooling system (e.g., processor 212) may determine the coolant fluid flow rate as Flow Rate 4, and so on. In some embodiments, the threshold temperature difference ranges and range flow rates may be derived from thermal simulations or measurements on actual vehicles or ECUs. Using ranges of the representative temperature difference may help providing smoother transitions in flow rate adjustments and may help minimize oscillations in flow rates caused when the flow rates are determined based on component temperatures, target temperatures or sudden changes in temperatures or environmental factors. Although five threshold temperature difference ranges have been described above, it should be understood that there may be any number of threshold temperature difference ranges with associated coolant fluid flow rate values.

In some embodiments, the at least one processor is configured to determine the range flow rate as a product of predetermined flow rate and the fraction associated with the identified threshold temperature difference range. For example in some embodiments, instead of storing a range flow rate value in association with the threshold temperature difference ranges, the range flow rate may be expressed as a percentage or fraction of the predetermined flow rate of the pump. Thus, for example, the memory may include five threshold temperature difference ranges and associated range flow rates expressed as follows:
Range 1: ΔT≤ΔT_{Limit-1} x1%
Range 2: ΔT_{Limit-1}<ΔT≤ΔT_{Limit-2} x2%
Range 3: ΔT_{Limit-2}<ΔT≤ΔT_{Limit-3} x3%
Range 4: ΔT_{Limit-3}<ΔT≤ΔT_{Limit-4} x4%
Range 5: ΔT>ΔT_{Limit-4} x4%
   When the range flow rate is expressed as a percentage, the one or more processors of the ECU and/or the dynamic cooling system (e.g., processor 212) may be configured to determine the range flow rate value as a product of the percentage and the predetermined flow rate of the pump. For example, when the representative temperature difference falls within Range 2, the corresponding range flow rate may be determined as x2% multiplied by the predetermined flow rate.

In some embodiments, the at least one processor is configured to select the range flow rate as the target flow rate. In some embodiments, the at least one processor is configured to determine the target flow rate as the range flow rate associated with the identified threshold temperature difference range. By way of example and referring to the prior example, when the representative temperature difference falls within Range 2, processor 212 may determine the target flow rate as Flow Rate 2 or the product of x2% and the predetermined flow rate.

In some embodiments, the at least one processor is configured to determine a target flow rate of the coolant fluid based on the plurality of temperature differences. For example, one or more processors of the ECU and/or the dynamic cooling system (e.g., processor 212) may be configured to determine the flow rate of the coolant fluid based on the representative temperature difference, which in turn is based on the plurality of temperature differences, as discussed above. In other embodiments, the one or more processors of the ECU and/or the dynamic cooling system (e.g., processor 212) may be configured to determine the target flow rate of the coolant fluid based on the temperature differences determined for a plurality of components of the ECU without determining a representative temperature difference. The one or more processors of the ECU and/or the dynamic cooling system (e.g., processor 212) may employ correlations, look-up tables, algorithms, and/or machine learning models similar to those described above to determine the flow rate of the coolant from the determined temperature differences. In some exemplary embodiments, the one or more processors of the ECU and/or the dynamic cooling system (e.g., processor 212) may determine a flow rate associated with each temperature difference. The one or more processors of the ECU and/or the dynamic cooling system (e.g., processor 212) may then determine a resultant flow rate as a maximum, minimum, average, other statistical combination, correlation, and/or other relationship between the determined flow rates for each of the temperature differences.

In some embodiments, the at least one processor is configured to select the predetermined flow rate as the target flow rate, when the representative temperature difference exceeds a maximum threshold temperature difference. In some embodiments, the at least one processor is further configured to select the predetermined flow rate as the target flow rate, when the representative temperature difference exceeds a maximum value of the upper threshold temperature difference of each threshold temperature difference range. In some embodiments, when the representative temperature difference exceeds a threshold value, the one or more processors of the ECU and/or the dynamic cooling system (e.g., processor 212) may select the predetermined or maximum flow rate of the pump as the target flow rate. For example, when the representative temperature difference is greater than the largest temperature difference in the stored threshold difference range, this condition may indicate that the components of the ECU are being insufficiently cooled and are operating at very high temperatures. In such conditions, the one or more processors of the ECU and/or the dynamic cooling system may be configured to supply the maximum (i.e., predetermined) flow rate of the coolant fluid in an attempt to cool down the components of the ECU. With reference to the above example, when processor 212 determines that the representative temperature difference is greater than ΔT_{Limit-4} or greater than all of ΔT_{Limit-1}, ΔT_{Limit-2}, ΔT_{Limit-3}, and ΔT_{Limit-4}, processor 212 may set the target flow rate as the predetermined flow rate associated with pump 204 of dynamic cooling system 200.

As discussed above, in some embodiments, the ECU may include more than one printed circuit board, each of which may include one or more components. In such a configuration, the cooling system may determine the target flow rate separately for each of the printed circuit boards by taking into account the respective components on each printed circuit board. The cooling system may then determine the target flow rate based on the flow rates determined for cooling the components of each of the printed circuit boards.

In some embodiments, the at least one processor is configured to determine a plurality of first temperature differences associated with the plurality of first components based on differences between first temperatures of the plurality of first components and respective first target temperatures associated with the plurality of first components. In some embodiments, the at least one processor is configured to determine a plurality of second temperature differences associated with the plurality of second components based on differences between second temperatures of the plurality of second components and respective second target temperatures associated with the plurality of second components. For example, in an ECU that has two printed circuit boards (e.g., first printed circuit board and second printed circuit board), the one or more processors of the ECU and/or the dynamic cooling system may determine the temperatures of one or more components attached to the first printed circuit board. The one or more processors of the ECU and/or the dynamic cooling system may also receive from the memory target temperatures corresponding to the one or more components attached to the first printed circuit board. Based on these values, the one or more processors of the ECU and/or the dynamic cooling system may determine one or more first temperature differences between the temperatures of the one or more components attached to the first printed circuit board and their corresponding target temperatures. Similarly, the one or more processors of the ECU and/or the dynamic cooling system may receive from the memory target temperatures corresponding to the one or more components attached to the second printed circuit board. Based on these values, the one or more processors of the ECU and/or the dynamic cooling system may determine one or more second temperature differences between the temperatures of the one or more components attached to the second printed circuit board and their corresponding target temperatures.

By way of example, the first printed circuit board may include component 1, component 2, and component 3, whereas the second printed circuit board may include component 4, component 5, and component 6. Processor 212 of dynamic cooling system 200 may receive temperatures T₁, T₂, T₃, T₄, T₅, and T₆ from temperature sensors 232 associated with component 1, component 2, component 3, component 4, component 5, and component 6, respectively. Further, processor 212 of dynamic cooling system 200 may receive target temperatures T_{TARGET-1}, T_{TARGET-2}, T_{TARGET-3}, T_{TARGET-4}, T_{TARGET-5}, T_{TARGET-6} for component 1, component 2, component 3, component 4, component 5, and component 6, respectively from memory 214. Processor 212 may be configured to determine temperature differences ΔT₁ (i.e., T₁−T_{TARGET-1}), ΔT₂ (i.e., T₂−T_{TARGET-2}), ΔT₃ (i.e., T₃−T_{TARGET-3}), ΔT₄ (i.e., T₄−T_{TARGET-4}), ΔT₅ (i.e., T₅−T_{TARGET-5}), and ΔT₆ (i.e., T₆−T_{TARGET-6}) for component 1, component 2, component 3, component 4, component 5, and component 6, respectively.

In some embodiments, the at least one processor is configured to determine a first representative temperature difference based on the plurality of first temperature differences. In some embodiments, the first representative temperature difference is one of a first maximum value or a first average value of the plurality of first temperature differences. In some embodiments, the at least one processor is configured to determine a second representative temperature difference based on the plurality of second temperature differences. In some embodiments, the second representative temperature difference is one of a second maximum value or a second average value of the plurality of second temperature differences. As discussed above, when the ECU has more than one printed circuit board, the one or more processors of the ECU and/or the dynamic cooling system may determine a representative temperature difference for each printed circuit board based on the temperature differences corresponding to the components mounted on that printed circuit board. For example, when there are two circuit boards, the one or more processors of the ECU and/or the dynamic cooling system may determine a first representative temperature difference, ΔT_{Rep-1}, for the first of the two printed circuit boards based on the first temperature differences as discussed above. Similarly, the one or more processors of the ECU and/or the dynamic cooling system may determine a second representative temperature difference, ΔT_{Rep-2}, for the second of the two printed circuit boards based on the second temperature differences as discussed above. The representative temperature differences (e.g., ΔT_{Rep-1} and ΔT_{Rep-2}) may be determined using any of the techniques discussed above, including for example, determining a maximum or an average temperature difference for each of the printed circuit boards.

Referring to the previous example, in which the first printed circuit board includes component 1, component 2, and component 3, and the second printed circuit board includes component 4, component 5, and component 6, processor 212 of dynamic cooling system 200 may determine ΔT_{Rep-1} for the first printed circuit board as a maximum or average value of ΔT₁, ΔT₂, and ΔT₃, and similarly may determine ΔT_{Rep-2} for the second printed circuit board as a maximum or average value of ΔT₄, ΔT₅, and ΔT₆.

In some embodiments, the at least one processor is configured to determine a first flow rate of the coolant fluid based on the first representative temperature difference. In some embodiments, the at least one processor is configured to determine a second flow rate of the coolant fluid based on the second representative temperature difference. As discussed above, when the ECU has more than one printed circuit board, the at least one processor may determine a representative temperature difference for each printed circuit board. Further, the at least one processor may determine a target flow rate for each printed circuit board based on any of the techniques discussed in this disclosure. For example, when there are two circuit boards, the one or more processors of the ECU and/or the dynamic cooling system may determine a first flow rate based on a first representative temperature difference associated with a first one of the two printed circuit boards, using any of the techniques discussed in this disclosure. Similarly, the one or more processors of the ECU and/or the dynamic cooling system may determine a second flow rate based on the second representative temperature difference associated with the second one of the two printed circuit boards, using any of the techniques discussed in this disclosure. Referring to the previous example, in which the first printed circuit board includes component 1, component 2, and component 3, and the second printed circuit board includes component 4, component 5, and component 6, processor 212 of dynamic cooling system 200 may determine a first flow rate FL1 based on the first representative temperature difference ΔT_{Rep-1}, and a second flow rate FL2 based on the second representative temperature difference ΔT_{Rep-2}.

In some embodiments, the at least one processor is configured to determine the target flow rate based on the first flow rate and the second flow rate. In some embodiments, the flow rate of the coolant fluid is one of a maximum flow rate value or an average flow rate value of the first flow rate and the second flow rate. As discussed above, when the ECU has more than one printed circuit board, the one or more processors of the ECU and/or the dynamic cooling system may determine a flow rate for each printed circuit board and then determine a target flow rate for the cooling system based on the determined flow rates. The target flow rate may be determined as a maximum of the flow rates for the different circuit boards, as an average of the flow rates for the different circuit boards, or using any other statistical calculation, mathematical expression, or algorithm applied to the flow rates for the different circuit boards. For example, when there are two circuit boards, the one or more processors of the ECU and/or the dynamic cooling system may determine the target flow rate as the greater of the first flow rate and the second flow rate or as an average of the first flow rate and the second flow rate. Referring to the previous example, in which the first printed circuit board includes component 1, component 2, and component 3, and the second printed circuit board includes component 4, component 5, and component 6, processor 212 of dynamic cooling system 200 may determine the target flow rate as a maximum of the first flow rate FL1 and the second flow rate FL2, or as an average of the first flow rate FL1 and the second flow rate FL2. Although only two printed circuit boards have been discussed above, it should be understood that the same procedure may be used to determine flow rates corresponding to more than two printed circuit boards. Similarly, the target flow rate may be determined based on a maximum, average, or any other combination of the flow rates associated with each of the more than two printed circuit boards.

In some embodiments, the at least one processor is configured to adjust at least one of the pump and the at least one control valve to deliver the target flow rate of the coolant fluid to flow through the cold plate. The one or more processors of the ECU and/or the dynamic cooling system may control one or more operational characteristics of the pump to ensure that the target flow rate of the coolant fluid is delivered by the pump to the cold plate. Additionally or alternatively, the one or more processors of the ECU and/or the dynamic cooling system may control the position of the movable element of a control valve to ensure that the control valve allows the target flow rate to flow in the tubing and piping associated with the cooling system.

By way of example, referring to FIG. 2, processor 212 may adjust the coolant fluid flow rate by adjusting a speed of pump 204, adjusting a position of a movable element of valve 206, or both so that the coolant fluid flow rate entering cold plate 12 is about equal to the target flow rate. In some exemplary embodiments, processor 212 may provide the target flow rate determined to ECU 10 or another controller in the vehicle that may control one or more of pump 204 and/or valve 206 to adjust the coolant fluid flow rate entering cold plate 12 to be about equal to the target flow rate. In some exemplary embodiments, processor 212 may convert the target flow rate to a percentage flow rate relative to the predetermined flow rate deliverable by pump 204, and output the determined percentage flow rate to ECU 10 or another controller.

In some embodiments, the at least one processor is configured to adjust at least one of the pump and the at least one control valve to modify a flow rate of the coolant fluid flowing through the cold plate. For example, the at least one processor may be configured to increase or decrease the flow rate of the coolant fluid from a first non-zero flow rate to a second non-zero flow rate.

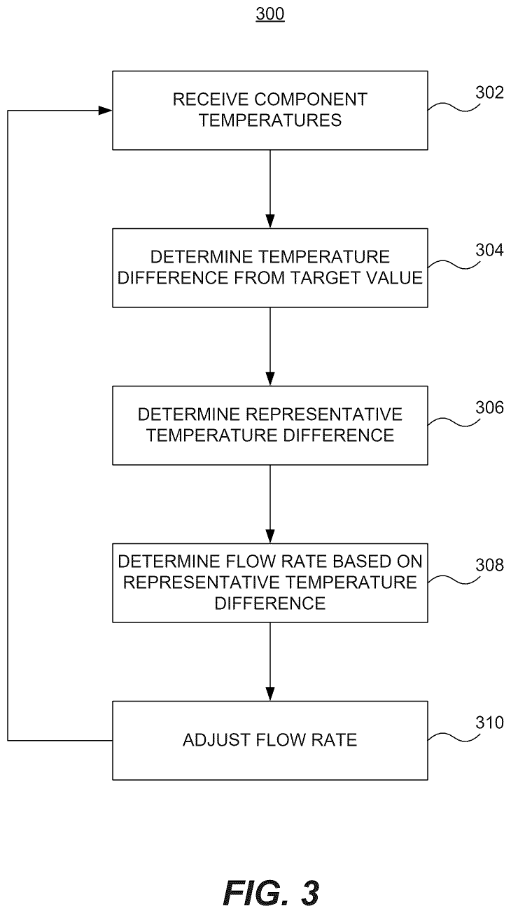

FIG. 3 illustrates a method 300 for operating dynamic cooling system 200. In some exemplary embodiments, method 300 may be performed by processor 212 of controller 210 or by a processor associated with, for example, ECU 10. The order and arrangement of steps in method 300 is provided for purposes of illustration. As will be appreciated from this disclosure, modifications may be made to method 300 by, for example, adding, combining, removing, and/or rearranging the steps of method 300.

Method 300 may include a step of receiving component temperatures (Step 302). In step 302, processor 212 of controller 210 may receive signals from the one or more temperature sensors 232 indicative of temperature of the one or more components 22 (e.g., component 1 through component N). For example, temperature sensors 232 associated with components 22 may measure temperatures T₁, T₂, . . . T_{N} corresponding to component 1, component 2, . . . component N, respectively. In some embodiments, temperatures T₁, T₂, . . . T_{N} may correspond to junction temperatures of one or more components 22 (e.g., component 1 through component N).

Method 300 may include a step of determining temperature differences relative to target temperature values for each of components 22 (Step 304). For example, each of components 22 (e.g., component 1 through component N) may have an associated target temperature. By way of example, component 1 may have a target temperature T_{TARGET-1}, component 2 may have a target temperature T_{TARGET-2}, component N may have a target temperature T_{TARGET-N} and so on. Target temperatures T_{TARGET-1}, T_{TARGET-2}, . . . T_{TARGET-N} may be equal or unequal. Target temperatures T_{TARGET-1}, T_{TARGET-2}, . . . T_{TARGET-N} may be predetermined and stored in, for example, memory 214. In some exemplary embodiments, target temperatures T_{TARGET-1}, T_{TARGET-2}, . . . T_{TARGET-N} may be a function of one or more vehicle operational parameters, and/or ambient conditions (e.g., temperature, pressure, humidity, altitude) and may be determined by processor 212 using a mathematical expression, an algorithm, or a look-up table.

In step 304, processor 212 may be configured to determine a difference in temperature between the component temperature received in, for example, step 302 and the target temperatures received in, for example, step 304. For example, processor 212 may determine a first temperature difference ΔT₁ for component 1 as the difference T₁−T_{TARGET-1}. Similarly, processor 212 may determine a second temperature difference ΔT₂ for component 2 as the difference T₂−T_{TARGET-2}, an Nth temperature difference ΔT_{N} for component N as the difference T_{N}−T_{TARGET-N}, and so on. Although a difference in temperatures has been discussed above, in some exemplary embodiments, processor 212 may determine a ratio of the measured and target temperatures for each component or may use any other type of statistical calculation or algorithm to determine a resultant value based on the measured and target temperatures for each component 22.

Method 300 may include a step of determining a representative temperature difference (Step 306) or a representative resultant value. In one exemplary embodiment, processor 212 may determine the representative temperature difference as a maximum value of the temperature differences determined, for example, in step 304. For example, the representative temperature difference may be a maximum of ΔT₁, ΔT₂, . . . ΔT_{N}. In some exemplary embodiments, processor 212 may determine the representative temperature difference as an average, median, mode, or any other statistical quantity based on the temperature differences determined, for example, in step 304. In some embodiments, processor 212 may determine the representative temperature difference based on any other mathematical combination of the temperature differences determined, for example, in step 304 or by performing operations on one or more the temperature differences determined, for example, in step 304 using any correlations, equations, or algorithms. Processor 212 may determine a representative resultant value by performing one or more operations similar to those discussed above on the one or more resultant values determined, for example, in step 304.

Method 300 may include a step of determining a flow rate of the coolant fluid based on the representative temperature difference or representative resultant value determined, for example, in step 306 (Step 308). In one exemplary embodiment, memory 214 may store correlations between the representative temperature difference or the representative resultant value and an associated flow rate. For example, memory 214 may store coolant flow rates for each of a plurality of threshold temperature difference ranges or threshold resultant values. Processor 212 may identify a particular threshold range out of the plurality of threshold ranges that may be associated with the representative temperature difference or the representative resultant value determined, for example, in step 306. Processor 212 may also access the coolant flow rate stored in memory 214 and associated with the particular range.

In some embodiments, in step 308, processor 212 may be configured to determine the flow rate of the coolant fluid based on the temperature differences determined, for example, in step 304 without determining a representative temperature difference. Processor 212 may employ correlations, look-up tables, algorithms, and/or machine learning models similar to those described above to determine the flow rate of the coolant from the determined temperature differences. In some exemplary embodiments, processor 212 may determine a flow rate associated with each temperature difference determined, for example, in step 304. Processor 212 may then determine a resultant flow rate as a maximum, minimum, average, other statistical combination, correlation, and/or other relationship between the determined flow rates for each of the temperature differences. Processor 212 may then adjust the coolant fluid flow rate entering the cold plate (as discussed below) so that the coolant fluid flow rate entering cold plate 12 is about equal to the resultant flow rate.

Method 300 may include a step of adjusting the coolant fluid flow rate entering the cold plate (Step 310). Processor 212 may adjust the coolant fluid flow rate by adjusting a speed of pump 204, adjusting the position of a movable element of valve 206 or both so that the coolant fluid flow rate entering cold plate 12 is about equal to the coolant fluid flow rate determined, for example, in step 308. In some exemplary embodiments, processor 212 may provide the coolant fluid flow rate determined, for example, in step 308 to ECU 10 or another controller in the vehicle that may control one or more of pump 204 and/or valve 206 to adjust the coolant fluid flow rate entering cold plate 12. In some exemplary embodiments, processor 212 may convert the coolant fluid flow rate determined, for example, in step 308 to a percentage flow rate relative to a maximum coolant fluid flow rate deliverable by pump 204, and output the determined percentage flow rate to ECU 10 or another controller.

After completing step 310, method 300 may return to step 302 and steps 302-310 may be repeatedly executed during operation of ECU 10 or the vehicle. In some exemplary embodiments, the steps 302-310 may be executed at a predetermined frequency, for example, 1 Hz, 2 Hz, 5 Hz, 10 Hz, or any other frequency within any other frequency range (e.g., 1-5 Hz, 5-10 Hz, 10-50 Hz, >50 Hz). In vehicle systems where ECU 10 components may be mounted to more than one printed circuit board, steps 302 through 308 may be performed for the components of each board separately. After the coolant fluid flow rate has been determined for each printed circuit board, processor 212 may determine a maximum value of the determined coolant fluid flow rates and may adjust the coolant fluid flow rate entering cold plate 12 based on that determined maximum value in a manner similar to that discussed above.

Unlike traditional “On/Off” cooling mechanisms, the disclosed dynamic cooling system and method may modulate flow rates based on precise thermal data, allowing for intermediate cooling levels that adapt to real-time needs. For example, the disclosed dynamic cooling system and method may help to conserve energy by reducing unnecessary power consumption when ECU 10 components are generating little to no heat by reducing the coolant fluid flow rate through ECU 10. Reducing the coolant fluid flow rate in turn reduces the amount of energy required to pump the coolant fluid through the cold plate, thereby conserving energy. The disclosed dynamic cooling system and method may also help to make gradual coolant fluid flow rate adjustments, reducing stress on cooling components, which in turn extends their operational life. The disclosed dynamic cooling system and method may account for varying thermal loads, ambient conditions, and coolant inlet temperatures to provide optimal cooling in all operational scenarios. In case of faults or communication loss, the disclosed dynamic cooling system and method may default to maximum cooling (100%) (e.g., to the maximum coolant fluid flow rate) to maintain thermal safety. Furthermore, in the disclosed dynamic cooling system and method, each monitored component contributes to the overall cooling request, ensuring that critical components are prioritized without unnecessarily cooling less demanding ones.

The foregoing description has been presented for purposes of illustration. It is not exhaustive and is not limited to the precise forms or embodiments disclosed. Modifications and adaptations will be apparent to those skilled in the art from consideration of the specification and practice of the disclosed embodiments. Moreover, while illustrative embodiments have been described herein, the scope of any and all embodiments having equivalent elements, modifications, omissions, combinations (e.g., of aspects across various embodiments), adaptations and/or alterations as would be appreciated by those skilled in the art based on the present disclosure. The limitations in the claims are to be interpreted broadly based on the language employed in the claims and not limited to examples described in the present specification or during the prosecution of the application. The examples are to be construed as non-exclusive. It is intended, therefore, that the specification and examples be considered as illustrative only, with a true scope and spirit being indicated by the following claims and their full scope of equivalents.

What is claimed is:

1. A dynamic cooling system for an electronic control unit (ECU), the system comprising:
a pump configured to deliver a flow of coolant fluid to a cold plate configured to cool a plurality of components in the ECU;
at least one control valve configured to control a flow rate of the coolant fluid;
at least one memory configured to store data and instructions; and
at least one processor configured to execute the instructions to:
receive, from a plurality of temperature sensors associated with the plurality of components, signals that are indicative of temperatures of the plurality of components;
determine a plurality of target temperatures associated with respective ones of the plurality of components;
determine a plurality of temperature differences associated with the plurality of components based on differences between the temperatures of the plurality of components and respective target temperatures associated with the plurality of components;
determine a target flow rate of the coolant fluid based on the plurality of temperature differences; and
adjust at least one of the pump and the at least one control valve to deliver the target flow rate of the coolant fluid to flow through the cold plate.

2. The dynamic cooling system of claim 1, wherein the at least one processor is further configured to determine the target flow rate of the coolant fluid by:
determining a representative temperature difference based on the plurality of temperature differences, and
determining the target flow rate based on the representative temperature difference.

3. The dynamic cooling system of claim 2, wherein the representative temperature difference is a maximum value of the plurality of temperature differences.

4. The dynamic cooling system of claim 2, wherein the representative temperature difference is an average value of the plurality of temperature differences.

5. The dynamic cooling system of claim 2, wherein the at least one processor is further configured to determine the target flow rate by:
comparing the representative temperature difference with a plurality of threshold temperature difference ranges;
identifying a threshold temperature difference range corresponding to the representative temperature difference, the identified threshold temperature difference range being one of the plurality of threshold temperature difference ranges;
determining a range flow rate associated with the identified threshold temperature difference range; and
selecting the range flow rate as the target flow rate.

6. The dynamic cooling system of claim 5, wherein
the pump is configured to deliver a predetermined flow rate of the coolant fluid,
each of the threshold temperature difference ranges is associated with a fraction of the predetermined flow rate,
and the at least one processor is configured to determine the range flow rate as a product of predetermined flow rate and the fraction associated with the identified threshold temperature difference range.

7. The dynamic cooling system of claim 2, wherein
the pump is configured to deliver a predetermined flow rate of the coolant fluid, and
the at least one processor is further configured to select the predetermined flow rate as the target flow rate, when the representative temperature difference exceeds a maximum threshold temperature difference.

8. The dynamic cooling system of claim 1, wherein
the ECU includes a first printed circuit board comprising a plurality of first components and a second printed circuit board comprising a plurality of second components, the first components and the second components being included in the plurality of components, and
the at least one processor is configured to determine the target flow rate by:
determining a plurality of first temperature differences associated with the plurality of first components based on differences between first temperatures of the plurality of first components and respective first target temperatures associated with the plurality of first components;
determining a plurality of second temperature differences associated with the plurality of second components based on differences between second temperatures of the plurality of second components and respective second target temperatures associated with the plurality of second components;
determining a first representative temperature difference based on the plurality of first temperature differences;
determining a second representative temperature difference based on the plurality of second temperature differences;
determining a first flow rate of the coolant fluid based on the first representative temperature difference;
determining a second flow rate of the coolant fluid based on the second representative temperature difference; and
determining the target flow rate based on the first flow rate and the second flow rate.

9. The dynamic cooling system of claim 8, wherein
the first representative temperature difference is one of a first maximum value or a first average value of the plurality of first temperature differences, and
the second representative temperature difference is one of a second maximum value or a second average value of the plurality of second temperature differences.

10. The dynamic cooling system of claim 8, wherein the flow rate of the coolant fluid is one of a maximum flow rate value or an average flow rate value of the first flow rate and the second flow rate.

11. A dynamic cooling system for an electronic control unit (ECU), the system comprising:
a pump configured to deliver a flow of coolant fluid to a cold plate configured to cool a first component and a second component in the ECU;
at least one control valve configured to control a flow rate of the coolant fluid;
a first temperature sensor configured to determine a first temperature of the first component;
a second temperature sensor configured to determine a second temperature of the second component;
at least one memory configured to store data and instructions; and
at least one processor configured to execute the instructions to:
receive signals from the first temperature sensor and the second temperature sensor, the signals being indicative of the first temperature and the second temperature, respectively;
receive, from the memory, a first target temperature associated with the first component and a second target temperature associated with the second component;
determine a first temperature difference associated with the first component based on the first temperature and the first target temperature;
determine a second temperature difference associated with the second component based on the second temperature and the second target temperature;
determine a representative temperature difference based on the first temperature difference and the second temperature difference;
determine a target flow rate of the coolant fluid based on the representative temperature difference; and
adjust at least one of the pump and the at least one control valve to deliver the target flow rate of the coolant fluid to flow through the cold plate.

12. The dynamic cooling system of claim 11, wherein the first target temperature is different from the second target temperature.

13. The dynamic cooling system of claim 11, wherein the representative temperature difference is a maximum value of the first temperature difference and the second temperature difference.

14. The dynamic cooling system of claim 11, wherein the representative temperature difference is an average value of the first temperature difference and the second temperature difference.

15. The dynamic cooling system of claim 11, wherein the at least one processor is further configured to:
receive, from the memory, a plurality of threshold temperature difference ranges and a range flow rate associated with each of the plurality of threshold temperature difference ranges;
compare the representative temperature difference with the plurality of threshold temperature difference ranges;
identify a threshold temperature difference range corresponding to the representative temperature difference, the identified threshold temperature difference range being one of the plurality of threshold temperature difference ranges; and
determine the target flow rate as the range flow rate associated with the identified threshold temperature difference range.

16. The dynamic cooling system of claim 15,
wherein the pump is configured to deliver a predetermined flow rate,
wherein each threshold temperature difference range includes at least a lower threshold temperature difference and an upper threshold temperature difference, and
wherein the at least one processor is further configured to select the predetermined flow rate as the target flow rate, when the representative temperature difference exceeds a maximum value of the upper threshold temperature difference of each threshold temperature difference range.

17. A method for cooling components in an electronic control unit (ECU), the method comprising:
receiving, from a first temperature sensor, a first temperature of a first component of the components in the ECU;
receiving, from a second temperature sensor, a second temperature of a second component of the components in the ECU;
determining a first temperature difference based on the first temperature and a first target temperature associated with the first component;
determine a second temperature difference based on the second temperature and a second target temperature associated with the second component;
determining a representative temperature difference based on the first temperature difference and the second temperature difference;
determining a target flow rate of a coolant fluid based on the representative temperature difference; and
directing the target flow rate of the coolant fluid to flow through a cold plate configured to cool the components in the ECU.

18. The method of claim 17, wherein determining the target flow rate further includes:
comparing the representative temperature difference with a plurality of threshold temperature difference ranges, each of the threshold temperature difference ranges being associated with a range flow rate;
identifying a threshold temperature difference range corresponding to the representative temperature difference;
identifying the range flow rate associated with the identified threshold temperature difference range; and
selecting the identified range flow rate as the target flow rate.

19. The method of claim 18, wherein
the range flow rate is expressed as a fraction of a predetermined flow rate associated with a pump configured to deliver the coolant fluid, and
determining the range flow rate includes obtaining a product of the fraction and the predetermined flow rate.

20. The method of claim 18, wherein the representative temperature difference is one of a maximum value or an average value of the first temperature difference and the second temperature difference.

21. A dynamic cooling system for an electronic control unit (ECU), the system comprising:
a pump configured to deliver a flow of coolant fluid to a cold plate configured to cool a plurality of components in the ECU;
at least one control valve configured to control a flow rate of the coolant fluid; and
at least one processor comprising circuitry and a memory, wherein the memory includes instructions that when executed by the circuitry cause the at least one processor to:
receive signals that are indicative of sensed temperatures of the plurality of components, the signals being based on detection signals of a plurality of temperature sensors associated with the plurality of components;
receive a plurality of target temperature regimes associated with respective ones of the plurality of components;
determine at least one flow rate parameter of the coolant fluid based on the sensed temperatures of the plurality of components and the plurality of target temperature regimes; and
adjust at least one of the pump and the at least one control valve to modify a flow rate of the coolant fluid flowing through the cold plate, in response to the at least one flow rate parameter.

22. The dynamic cooling system of claim 21 wherein, after modifying the flow rate, the processor is further configured to:
receive second signals that are indicative of second sensed temperatures of the plurality of components, the second signals being based on second detection signals of the plurality of temperature sensors;
determine a temperature changes of at least one component of the plurality of components based on at least one second sensed temperature of the respective at least one component;
determine at least one second flow rate parameter of the coolant fluid based on the second sensed temperatures of the plurality of components and the plurality of target temperature regimes; and
adjust at least one of the pump and the at least one control valve to increase the flow rate of the coolant fluid to flow through the cold plate, in response to the at least one second flow rate parameter.

23. The dynamic cooling system of claim 21, wherein the processor is further configured to modify the flow rate from a first non-zero flow rate to a second non-zero flow rate.

24. The dynamic cooling system of claim 21, wherein at least one of the target temperature regimes includes a target temperature.
